(19) United States
(12) Patent Application Publication
(10) Pub. No.: US 2014/0146499 A1
(43) Pub. Date: May 29, 2014

(54) PRINTED CIRCUIT BOARD AND DEVICE INCLUDING THE SAME

(71) Applicant: Samsung Electronics Co., Ltd., Gyeonggi-do (KR)

(72) Inventors: Wonjea Jang, Gyeonggi-do (KR); Jaewoong Kim, Gyeonggi-do (KR); Taewoo Kim, Gyeonggi-do (KR)

(73) Assignee: Samsung Electronics Co., Ltd., Gyeonggi-do (KR)

(21) Appl. No.: 14/092,771

(22) Filed: Nov. 27, 2013

(30) Foreign Application Priority Data
Nov. 29, 2012 (KR) 10-2012-0136644

(51) Int. Cl. H05K 1/02

(52) U.S. Cl. CPC H05K 1/0213
USPC 361/761; 174/260

(57) ABSTRACT

A printed circuit board (PCB) having a decoupling capacitor includes: a PCB including a power supply layer, ground layer, and first decoupling capacitor; a package mounted at a surface of the PCB, wherein the first decoupling capacitor is embedded in a via hole of the PCB, and a first electrode of the first decoupling capacitor is connected to one of power supply pins of the package, and a second electrode of the first decoupling capacitor is connected to the ground layer.

### CROSS-REFERENCE TO RELATED APPLICATION(S) AND CLAIM OF PRIORITY

The present application is related to and claims the benefit under 35 U.S.C. §119 (a) of a Korean patent application filed on Nov. 29, 2012 in the Korean Intellectual Property Office and assigned Serial No. 10-2012-0136644, the entire disclosure of which is hereby incorporated by reference.

### TECHNICAL FIELD

The present application relates to a printed circuit board having a decoupling capacitor and a device including the same.

### BACKGROUND

A decoupling capacitor is disposed between a power source and the ground (GND), and prevents damage to an integrated circuit (IC) from an instantaneous overcurrent. That is, a direct current (DC), which is a power source component is input to an IC, and an alternating current (AC), which is a noise component, flows to the ground through the decoupling capacitor. Further, when an input voltage of the IC drops with a change in current, the decoupling capacitor supplies a current within the decoupling capacitor to the IC, thereby maintaining a constant input voltage to the IC.

The decoupling capacitor (hereinafter, a decap) can be disposed at various positions in a printed circuit board (PCB). For example, the decap is mounted together with the IC at a surface of the PCB using surface mounting technology (SMT).

FIG. 1 is a cross-sectional view illustrating a device related to the present disclosure, and FIG. 2 is a circuit diagram illustrating a flow of a current in the device of FIG. 1.

Referring to FIG. 1, a device 100 includes a PCB 110, a power management IC (PMIC) 120, a bulk capacitor 130, a package 140, an IC 150, first to fourth decaps 161 to 164, and bumps 170.

At a surface of the PCB 110, the PMIC 120, package 140, and first to fourth decaps 161 to 164 are mounted. The bumps 170 connect power supply pins and ground pins of the package 140 to a power supply line 111 and a ground line 112, respectively, of the PCB 110. At a surface of the package 140, the IC 150 is mounted. At the IC 150, a first electrode and a second electrode are connected to a power supply line 141 and a ground line 142 of the package 140.

The first decap 161 and the second decap 162 are mounted at the surface of the PCB 110. Referring to FIGS. 1 and 2, at the first decap 161 and the second decap 162, the first electrode and the second electrode are connected to the power supply line 111 and the ground line 112, respectively. The first decap 161 and the second decap 162 prevent an instantaneous overcurrent from being injected into the package 140. Further, by supplying a current 210 to the package 140, the first decap 161 and the second decap 162 constantly maintain an input voltage of the package 140.

The third decap 163 and the fourth decap 164 are mounted at the surface of the package 140. Referring to FIGS. 1 and 2, the third decap 163 and the fourth decap 164 prevent an instantaneous overcurrent from being injected into the IC 150. Further, by supplying a current 220 to the IC 150, the third decap 163 and the fourth decap 164 constantly maintain an input voltage of the IC 150.

The bulk capacitor 130 is used for stabilization of a voltage and is disposed beside the PMIC 120 like a decap.

Referring again to FIG. 1, when a distance A between the first decap 161 and the power supply pin increases, a length of a wiring B that connects the first decap 161 and the power supply pin increases and impedance of the power supply line increases. For example, when the distance A increases from 0 to 1.0 mm, impedance increases to 7.7 dB, and when the distance A increases from 0 to 2.0 mm, impedance increases to 11.5 dB, when the distance A increases from 0 to 5.0 mm, impedance increases to 18.3 dB, and when the distance A increases from 0 to 10.0 mm, impedance increases to 23.1 dB. As described above, as the distance A increases, impedance of the power supply line increases and power integrity (PI) drops. That is, a voltage that is input to the IC and the package is not constant. Therefore, the decap is disposed adjacent to the IC. However, because the decap is mounted at a surface of the PCB together with the IC, a limitation exists in shortening a length of the wiring B. Further, at the surface of the PCB, a plurality of decaps are mounted. Therefore, when designing the PCB, mounted space of the decap should be secured, and it can be difficult to wire the decap and the IC.

### SUMMARY

To address the above-discussed deficiencies of the related art, it is a primary object to provide a PCB and a device including the same that improve PI by reducing impedance of a power supply line and having no restriction of mounted space and a wiring.

In certain embodiments, a device includes: a PCB including a power supply layer, ground layer, and first decap; a package mounted at a surface of the PCB, wherein the first decap is embedded in a via hole of the PCB, and a first electrode of the first decap is connected to one of power supply pins of the package, and a second electrode of the first decap is connected to the ground layer.

In certain embodiments, a device includes: a PCB including a power supply layer, a ground layer, and a decap; an integrated circuit mounted at a surface of the PCB, wherein the decap is embedded in a via hole of the PCB, and a first electrode of the decap is connected to one of power supply pins of the integrated circuit, and a second electrode of the decap is connected to the ground layer.

In certain embodiments, a PCB includes: conductive layers; insulating layers each interposed between the conductive layers; and a decap including a first electrode embedded in a via hole and connected to a power supply layer of the conductive layers or exposed at a surface through the via hole, a second electrode connected to a ground layer of the conductive layers, and a dielectric substance interposed between the first electrode and the second electrode.

In certain embodiments, a mobile terminal includes: a PCB including a power supply layer, ground layer, and decap; a package mounted at a surface of the PCB, wherein the decap is embedded in the via hole of the PCB, and a first electrode of the decap is connected to one of power supply pins of the package, and a second electrode of the decap is connected to the ground layer.

Before undertaking the DETAILED DESCRIPTION below, it can be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller can be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a cross-sectional view illustrating a device related to the present disclosure;

FIG. 2 is a circuit diagram illustrating a flow of a current in the device of FIG. 1;

FIG. 3 is a cross-sectional view illustrating a device according to certain embodiments;

FIG. 4 is a cross-sectional view illustrating a device according to certain embodiments;

FIG. 5 is a cross-sectional view illustrating a device according to certain embodiments;

FIGS. 6 and 7 are cross-sectional views illustrating a PCB according to certain embodiments; and

FIG. 8 is a cross-sectional view illustrating a PCB according to certain embodiments.

### DETAILED DESCRIPTION

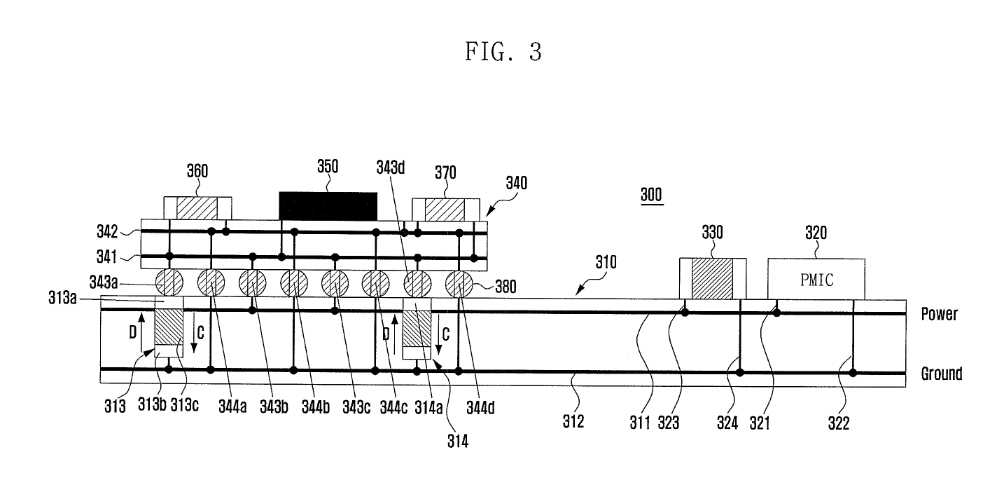

FIGS. 3 through 8, discussed below, and the various embodiments used to describe the principles of the present disclosure in this patent document are by way of illustration only and should not be construed in any way to limit the scope of the disclosure. Those skilled in the art will understand that the principles of the present disclosure can be implemented in any suitably arranged electronic device. Hereinafter, exemplary embodiments of the present disclosure are described in detail with reference to the accompanying drawings. The same reference numbers are used throughout the drawings to refer to the same or like parts. The views in the drawings are schematic views only, and are not intended to be to scale or correctly proportioned. Detailed descriptions of well-known functions and structures incorporated herein can be omitted to avoid obscuring the subject matter of the present disclosure.

In the present disclosure, it means a direct connection or an indirect connection that an element (e.g., an IC) is connected to another element (e.g., a decap). Here, a direct connection means that another element is not interposed between two elements, and an indirect connection means that at least one element is interposed between two elements.

FIG. 3 is a cross-sectional view illustrating a device according to an exemplary embodiment of the present disclosure. Referring to FIG. 3, a device 300 according to the present embodiment includes a PCB 310 including a first decap 313 and a second decap 314, a PMIC 320, a bulk capacitor 330, a package 340, an IC 350, a third decap 360, a fourth decap 370, and bumps 380.

The PCB 310 includes a power supply line 311, ground line 312, the first decap 313, and the second decap 314. The first decap 313 is positioned at the inside of the PCB 310. Particularly, the first decap 313 is embedded in a via hole of the PCB 310. The first decap 313 includes a first electrode 313a, second electrode 313b, and dielectric substance interposed between the electrodes 313a and 313b. The first electrode 313a is exposed at a surface through a via hole of the PCB 310, and the second electrode 313b is connected to the ground line 312. The first decap 313 prevents an instantaneous overcurrent A from being injected into the package 340. That is, an overcurrent C is not injected into the package 340 and flows to the ground line 312 through the first decap 313. Further, the first decap 313 receives supply of a current from the PMIC 320, accumulates the current, and supplies an accumulated current D to the package 340, thereby constantly maintaining an input voltage of the package 340. The second decap 314 is formed similar to the first decap 313. The PCB 310 is designed in a structure having several conductive layers (e.g., six layers and ten layers). An insulator is interposed between conductive layers. For example, the PCB 310 can have a six layer structure, and here, a third layer can be a power supply layer including the power supply line 311 and a four layer can be a ground layer including the ground line 312. A sixth layer can be also a ground layer. The remaining layers each can be signal layers including a signal line. A structure of the PCB is not limited thereto. This is, for example, a second layer can be a power supply layer and a third layer can be a signal layer. The decaps 313 and 314 are embedded in a via hole that penetrates from a first layer (surface) to a ground layer, for example, a four layer or a sixth layer.

The PMIC 320 is mounted at a surface of the PCB 310. A first electrode, i.e., a power supply electrode of the PMIC 320 is connected to the power supply line 311 through first via 321, and a second electrode, i.e., a ground electrode is connected to the ground line 312 through second via 322 to supply power to the package 340. Here, the first via 321 is an electric conductor (e.g., copper) inserted into a via hole that penetrates from a first layer (surface) to a layer (e.g., a third layer) having the power supply line 311. The second via 322 is an electric conductor inserted into a via hole that penetrates from a first layer (surface) to a layer (e.g., a fourth layer) having a ground line 313.

The bulk capacitor 330 is mounted at a surface of the PCB 310 and is positioned adjacent to the PMIC 320. A first electrode of the bulk capacitor 330 is connected to the power supply line 311 through third via 323, and a second electrode thereof is connected to the ground line 312 through fourth via 324. The bulk capacitor 330 receives supply of a current from the PMIC 320 and accumulates a current. When an output voltage of the PMIC 320 is not stable, i.e., when a voltage drops, by supplying an accumulated current to the package 340, the bulk capacitor 330 maintains a constant input voltage of the package 340.

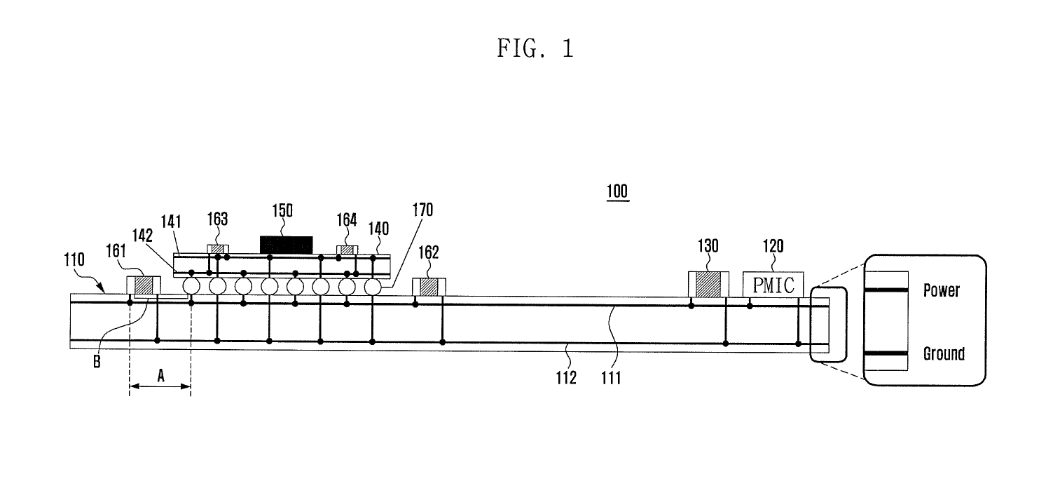

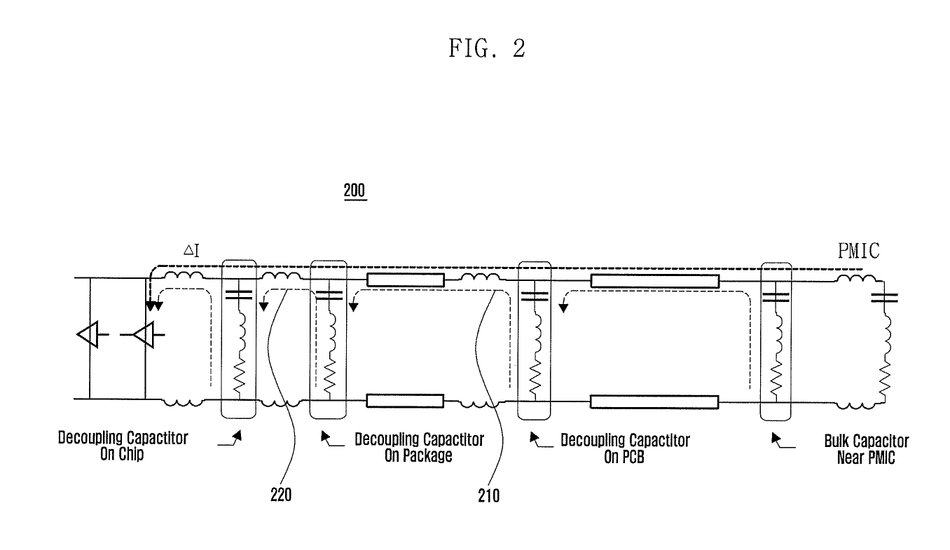

The package 340 includes a power supply line 341, a ground line 342, a plurality of power supply pins 343a to 343d, and a plurality of ground pins 344a to 344d. The pins 343a to 343d and 344a to 344d are positioned at a rear surface of the package 340. The package 340 is mounted at a surface of the PCB 310. The plurality of power supply pins 343a to 343d each are connected to the power supply line 341 through vias. The plurality of ground pins 344a to 344d each are connected to the ground line 342 through the vias. Particularly, at least one of the plurality of power supply pins 343a to 343d is connected to a decap positioned at the inside of the PCB 310. For example, the first power supply pin 343a is directly connected to the first electrode 313a of the first decap 313. The second power supply pin 343d is directly connected to a first electrode 314a of the second decap 314. A length of a wiring that connects a power supply pin of the package and the decap is remarkably reduced, compared with another case (e.g., FIG. 1). Therefore, PI is improved, and a decap is embedded at the inside of a PCB, compared with another case, and thus the PCB is free from restriction of mounted space and a wiring. Other power supply pins 343b and 343c each are connected to the power supply line 311 of the PCB 310 through vias.

The IC 350 is mounted at a surface of the package 340. A first electrode, i.e., a power supply electrode of the IC 350 is connected to the power supply line 341 of the package 340 through via, and a second electrode, i.e., a ground electrode is connected to the ground line 342 of the package 340 through via.

The third decap 360 is mounted at a surface of the package 340. A first electrode of the third decap 360 is connected to the power supply line 341 of the package 340 through via, and a second electrode thereof is connected to the ground line 342 of the package 340 through via. The fourth decap 370 is formed similar to the third decap 360.

The bumps 380 bond a power supply pin and a ground pin of the package 340 to a surface of the PCB 310. Such bumps 380 can be formed by ball bonding.

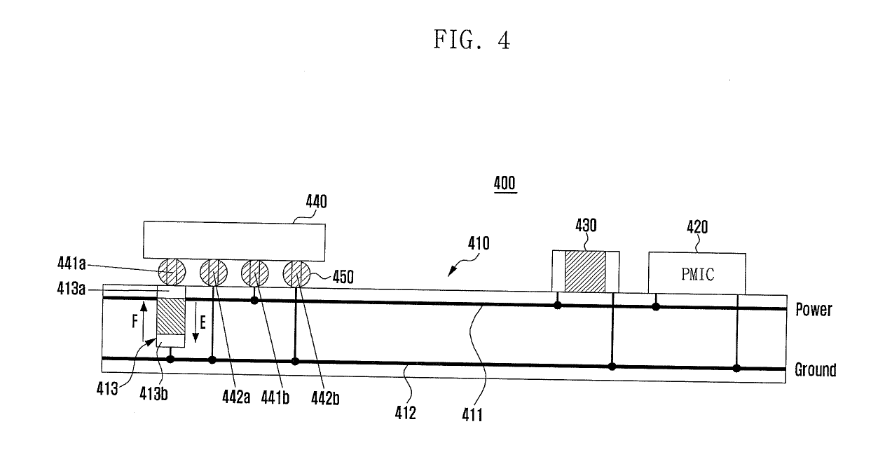

FIG. 4 is a cross-sectional view illustrating a device according to certain embodiments.

Referring to FIG. 4, a device 400 includes a PCB 410, a PMIC 420, a bulk capacitor 430, an IC 440, and bumps 450.

The PCB 410 includes a power supply line 411, ground line 412, and decap 413. The decap 413 is positioned at the inside of the PCB 410. A first electrode 413a of the decap 413 is positioned at the surface of the PCB 410, and a second electrode 413b thereof is connected to the ground line 412. An overcurrent E is not injected into the package 340 and flows to the ground line 412 through the decap 413. The decap 413 receives supply of a current from the PMIC 420 and accumulates a current, and supplies an accumulated current F to the IC 440, thereby maintaining a constant input voltage of the IC 440.

The PMIC 420 is mounted at a surface of the PCB 410, and a first electrode, i.e., a power supply electrode of the PMIC 420 is connected to the power supply line 411 through via, and a second electrode, i.e., a ground electrode is connected to the ground line 412 through another via. The bulk capacitor 430 is mounted at the surface of the PCB 410 and is positioned adjacent to the PMIC 420.

The IC 440 includes a plurality of power supply pins 441a and 441b and a plurality of ground pins 442a and 442b. The pins 441a, 441b, 442a, and 442b are positioned at a rear surface of the IC 440. The IC 440 is mounted at the surface of the PCB 410. The plurality of power supply pins 441a and 441b each are connected to the power supply line 411 through vias. The plurality of ground pins 442a and 442b each are also connected to the ground line 412 through vias. Particularly, at least one of the plurality of power supply pins 441a to 441b is connected to a decap embedded in a via hole of the PCB 410. For example, the first power supply pin 441a is directly connected to the first electrode 413a of the decap 413. A length of a wiring that connects a power supply pin of an IC and a decap is remarkably reduced, compared with another case (e.g., FIG. 1). Therefore, PI is improved and a decap is embedded at the inside of a PCB, compared with another case, and thus the PCB is free from restriction of mounted space and a wiring. The second power supply pin 441b is connected to the power supply line 411 of the PCB 410 through via.

The bumps 450 bond a ground pin and a power supply pin of the IC 440 to a surface of the PCB 410.

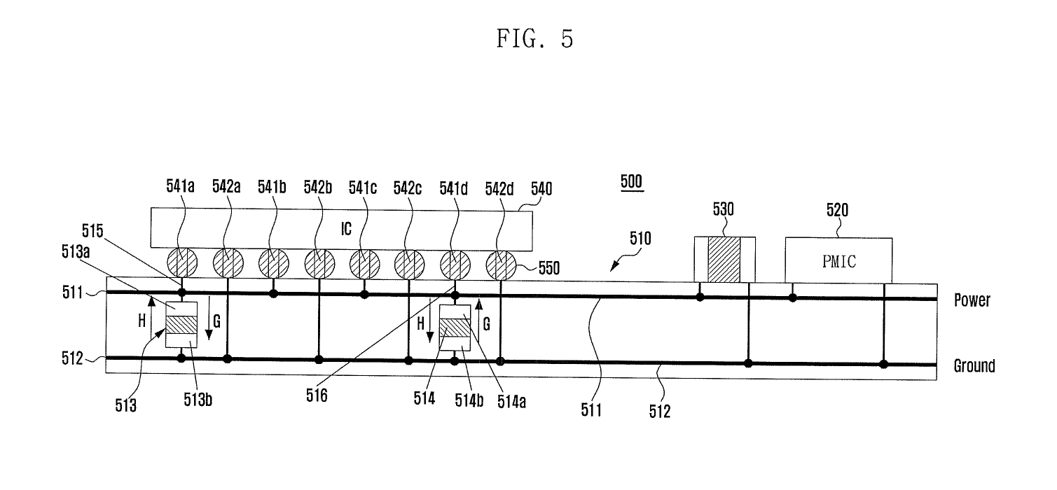

FIG. 5 is a cross-sectional view illustrating a device according to certain embodiments. Referring to FIG. 5, a device 500 includes a PCB 510, a PMIC 520, a bulk capacitor 530, an IC 540, and bumps 550.

The PCB 510 includes a power supply line 511, ground line 512, first decap 513, and second decap 514. The decaps 513 and 514 are positioned at the inside of the PCB 510. First electrodes 513a and 514a of the first decap 513 each are connected to the power supply line 511, and second electrodes 513b and 514b thereof each are connected to the ground line 512. For example, the PCB 510 can have a ten layer structure, and a third layer can be a power supply layer including the power supply line 511, and a sixth layer can be a ground layer including the ground line 512. In this case, the decaps 513 and 514 each are embedded in a via hole that penetrates from a third layer to a sixth layer. An overcurrent G is not injected into the IC 540 and gets out to the ground line 512 through the decaps 513 and 514. The decaps 513 and 514 receive supply of a current from the PMIC 520, accumulate the current, and supplies an accumulated current H to the IC 540, thereby constantly maintaining an input voltage of the IC 540.

The IC 540 includes a plurality of power supply pins 541a to 541d and a plurality of ground pins 542a to 542d. The pins 541a to 541d and 542a to 542d are positioned at a rear surface of the IC 540. The IC 540 is mounted at a surface of the PCB 510. The plurality of power supply pins 541a to 541d each are connected to the power supply line 511 through vias. The plurality of ground pins 542a to 542d each are connected to the ground line 512 through vias. Particularly, at least one of the plurality of power supply pins 541a to 541d is connected to a decap positioned at the inside of the PCB 510 through via. For example, the first power supply pin 541a is connected to the first electrode 513a of the first decap 513 through first via 515. Further, the second power supply pin 541d is connected to the first electrode 514a of the second decap 514 through a second via 516. A length of a wiring that connects a power supply pin of the IC and a decap is remarkably reduced, compared with another case (e.g., FIG. 1). Therefore, PI is improved and a decap is embedded in the inside of a PCB, compared with another case, and thus the PCB is free from restriction of mounted space and a wiring.

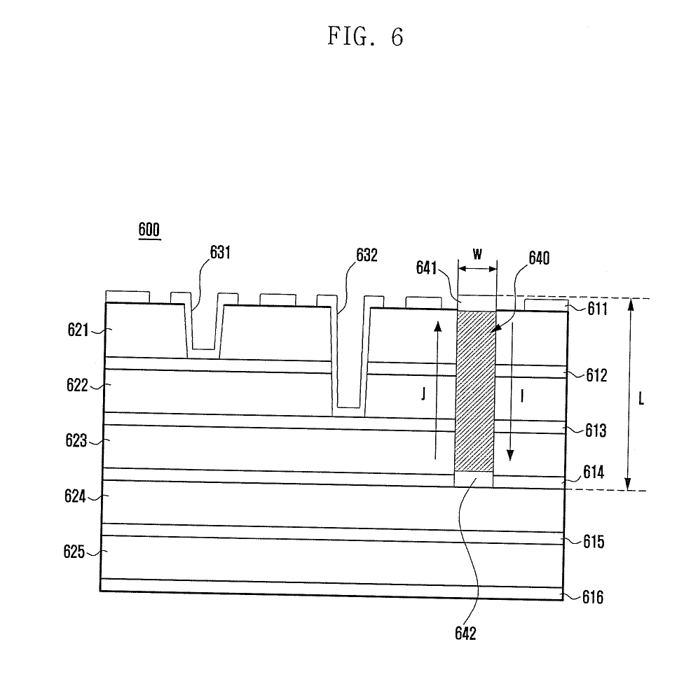

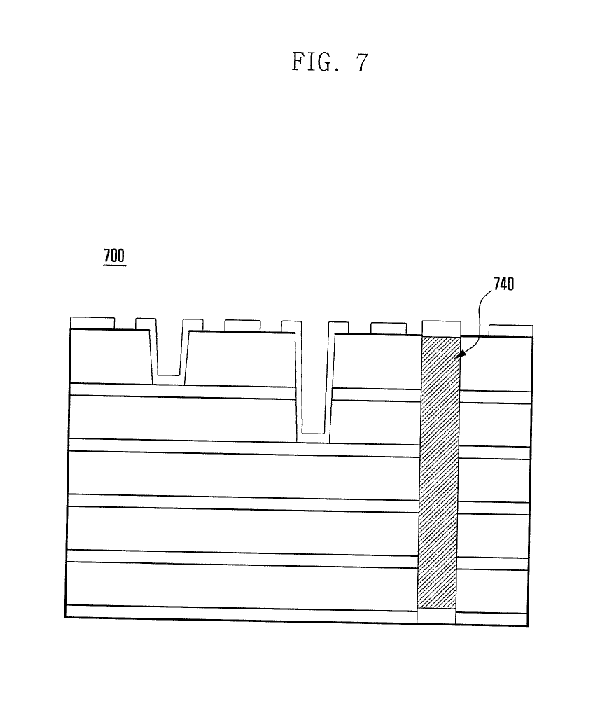

FIGS. 6 and 7 are cross-sectional views illustrating a PCB according to certain embodiments. Referring to FIG. 6, a PCB 600 includes conductive layers 611 to 616, and insulating layers 621 to 625 interposed between the conductive layers 611 to 616, vias 631 and 632, and at least one decap 640 embedded in the PCB 600.

The decap 640 is embedded in a via hole that penetrates a surface of the PCB 600, i.e., from a first layer 611 to a ground layer, for example, a fourth layer 614. Although not limited to a specific dielectric substance, for example, an electrolyte or ceramic is injected into a via hole and thus the decap 640 is produced. In other words, a method of manufacturing a PCB according to the present exemplary embodiment includes boring a via hole, injecting paste (e.g., ceramic paste) into the via hole (a silk screen printing method), drying (e.g., drying during 30 minutes at 150° C.-170° C.) a PCB to harden the injected paste, and forming a first electrode and a second electrode at both surfaces, respectively of dried paste.

A first electrode 641 of the decap 640 is exposed to the outside through a surface of the PCB 600, and a second electrode 642 thereof is connected to a ground layer, for example, a fourth layer. Although not shown, the first electrode 641 is connected to a power supply pin of an IC (or a package). Therefore, an overcurrent I is not injected into an IC (or package) and flows to a fourth layer through the decap 640. The decap 640 accumulates a current, and supplies an accumulated current J to an IC (or a package), thereby maintaining a constant input voltage of the IC (or the package).

Referring to FIG. 7, a ground layer can be formed in another layer, for example, a sixth layer instead of a fourth layer. Accordingly, a decap 740 is embedded in a via hole that penetrates from a surface of a PCB 700 to a sixth layer.

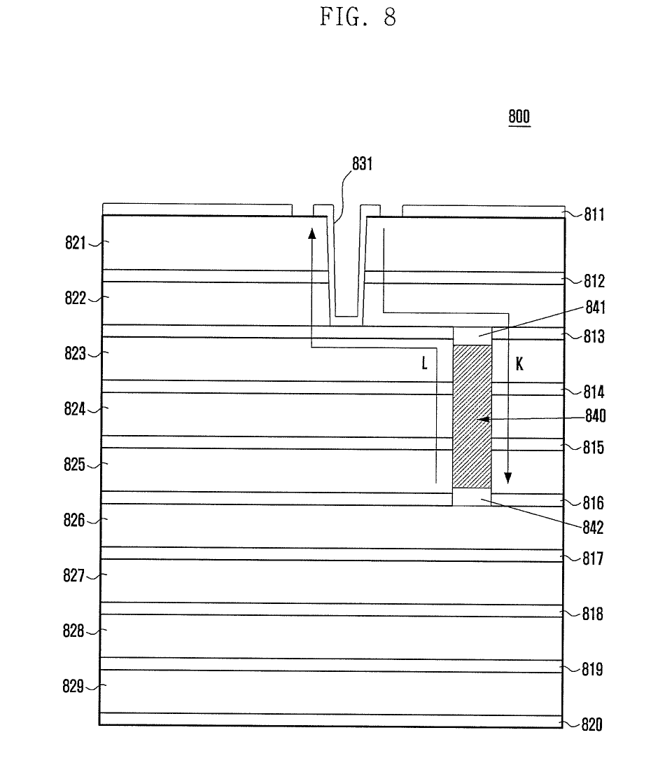

FIG. 8 is a cross-sectional view illustrating a PCB according to certain embodiments. A PCB 800 includes conductive layers 811 to 820, insulating layers 821 to 829 interposed between the conductive layers 811 to 820, via 831, and at least one decap 840 embedded in the PCB 800.

The via 831 connects a first layer 811 and a third layer 813. Here, the third layer 813 is a power supply layer. The decap 840 is embedded in a via hole that penetrates from a power supply layer, i.e., the third layer 813 to a ground layer, for example, a sixth layer 816. A first electrode 841 of the decap 840 is connected to the third layer 813, and a second electrode 842 thereof is connected to the sixth layer 816. Although not shown, the first electrode 841 is connected to a power supply pin of an IC (or a package) through the via 831. Therefore, an overcurrent K is not injected into the IC (or the package) and flows to the sixth layer 816 through the decap 840. The decap 840 accumulates a current and supplies an accumulated current L to an IC (or a package), thereby maintaining a constant input voltage of the IC (or the package).

In FIGS. 6 to 8, a thickness of a conductive layer can be designed in 12 μm or 17.5 μm. A thickness of an insulating layer can be designed in 60 μm or 100 μm. A PCB includes a surface mounting decap and an embedded decap. When a PCB is designed, decaps are divided into surface mounting decaps and embedded decaps based on a capacitance value. For example, it is assumed that 13 decaps of 100 nF, 6 decaps of 1000 nF, 2 decaps of 2200 nF, 2 decaps of 4700 nF, and 1 decap of 220 nF are necessary for the PCB. 13 decaps of 100 nF having the highest use frequency and 6 decaps of 1000 nF having the second highest use frequency are determined as embedding decaps according to the present disclosure. The remaining decaps are determined as surface mounting decaps. Entire decaps can be determined as an embedding decap regardless of the use frequency.

Further, when a PCB is designed, decaps are divided into surface mounting decaps and embedding decaps based on a length of a via hole. For example, it is assumed that a length of a via hole that penetrates from the first layer 611 to the fourth layer 614 is 0.3 millimeters or more. Therefore, a surface mounting decap in which a length L is 0.4 millimeters and a thickness W is 0.2 millimeters can be replaced with an embedded decap.

Further, in the foregoing exemplary embodiments, it is illustrated that aground line is positioned under a power supply line, but can be positioned on a power supply line.

A device according to the present disclosure can be, for example, used in a computer such as a personal computer (PC) and a laptop computer, mobile terminal such as a smart phone, mobile phone, potable media player (PMP), tablet PC, navigation terminal, and game player, and household appliances such as an audio/video (AV) device, television (TV), smart hub device, and file server.

As described above, according to a PCB, device, and mobile terminal of the present disclosure, by reducing impedance of a power supply line, PI is improved and the PCB and the device including the PCB are freed from restrictions in the mounting space and wiring.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A device, comprising:
a printed circuit board (PCB) comprising a power supply layer, ground layer, and first decoupling capacitor (decap); and
a package mounted at a surface of the PCB, the package having at least one power supply pin,
wherein the first decap is embedded in a via hole of the PCB, and a first electrode of the first decap is connected to the at least one power supply pin of the package, and a second electrode of the first decap is connected to the ground layer.

2. The device of claim 1, wherein the via hole penetrates from a surface of the PCB to the ground layer.

3. The device of claim 2, wherein the first electrode of the first decap is exposed at the surface of the PCB through the via hole and is directly connected to the at least one power supply pin of the package.

4. The device of claim 1, wherein the via hole penetrates from the power supply layer to the ground layer.

5. The device of claim 4, wherein the first electrode of the first decap is connected to the power supply layer.

6. The device of claim 1, further comprising a second decap mounted at the surface of the PCB,
wherein the second decap has a use frequency lower than that of the first decap.

7. A device, comprising:
a printed circuit board (PCB) comprising a power supply layer, ground layer, and decap;
an integrated circuit mounted at a surface of the PCB, the integrated circuit having at least one power supply pin,
wherein the decap is embedded in a via hole of the PCB, and a first electrode of the decap is connected to the at least one power supply pin of the integrated circuit, and a second electrode of the decap is connected to the ground layer.

8. The device of claim 7, wherein the via hole penetrates from a surface of the PCB to the ground layer.

9. The device of claim 8, wherein the first electrode of the decap is exposed at the surface of the PCB through the via hole and is directly connected to the at least one power supply pin of the package.

10. The device of claim 7, wherein the via hole penetrates from the power supply layer to the ground layer.

11. The device of claim 10, wherein the first electrode of the decap is connected to the power supply layer.

12. The device of claim 7, further comprising another decap mounted at the surface of the PCB,
wherein another decap has a use frequency lower than that of the decap.

13. A printed circuit board (PCB), comprising:
conductive layers;
insulating layers each interposed between the conductive layers; and
a decap comprising a first electrode, a second electrode connected to a ground layer of the conductive layers, and a dielectric substance interposed between the first electrode and the second electrode.

14. The PCB of claim 13, wherein the via hole penetrates from the surface to the ground layer.

15. The PCB of claim 14, wherein the ground layer is one of a fourth layer and a sixth layer.

16. The PCB of claim 13, wherein the first electrode is embedded in a via hole and connected to a power supply layer of the conductive layers.

17. The PCB of claim 13, wherein the first electrode is exposed at a surface through the via hole.

18. A mobile terminal, comprising:
a printed circuit board (PCB) comprising a power supply layer, a ground layer, and a decap;
a package mounted at a surface of the PCB, the package having at least one power supply pin,
wherein the decap is embedded in the via hole of the PCB, and a first electrode of the decap is connected to the at least one power supply pin of the package, and a second electrode of the decap is connected to the ground layer.

19. The device of claim 18, wherein the via hole penetrates from a surface of the PCB to the ground layer.

20. The device of claim 18, wherein the via hole penetrates from the power supply layer to the ground layer.
